(19) United States
(12) Patent Application Publication
(10) Pub. No.: US 2026/0227712 A1
(43) Pub. Date: Aug. 6, 2026

(54) STAGE APPARATUS, LITHOGRAPHY APPARATUS, ARTICLE MANUFACTURING METHOD, AND DRIVING METHOD FOR STAGE APPARATUS

(71) Applicant: CANON KABUSHIKI KAISHA, Tokyo (JP)

(72) Inventors: KEISUKE KUWABARA, Tochigi (JP); TAKASHI HAYAKAWA, Tochigi (JP); NORIHIRO SAKURAKAWA, Tochigi (JP)

(21) Appl. No.: 19/461,841

(22) Filed: Jan. 28, 2026

(30) Foreign Application Priority Data
Jan. 30, 2025 (JP) 2025-014097

(51) Int. Cl. G03F 7/00

(52) U.S. Cl. CPC G03F 7/70725

(57) ABSTRACT

A stage apparatus is provided. The stage apparatus includes: a first stage; a first actuator configured to drive the first stage; a second stage supported by the first stage; a second actuator configured to contactlessly transmit a thrust applied to the first stage by the first actuator to the second stage; a driver configured to drive the second actuator; and a controller configured to control the first actuator and the driver. In a case of applying an electric brake to the first stage by using the first actuator, the controller is configured to apply the electric brake after a lapse of a predetermined time since output of control signal for controlling the second actuator from the driver is stopped.

### BACKGROUND

### Field of the Technology

The present disclosure relates to a stage apparatus, a lithography apparatus, an article manufacturing method, and a driving method for the stage apparatus.

### DESCRIPTION OF THE RELATED ART

A stage apparatus needs to have a fail safe mechanism that brings a stage to an emergency stop to prevent the behavior of the stage from going out of control when a trouble occurs during the driving of the stage. Japanese Patent Laid-Open No. 2001-085503 discloses a technique of stopping the stage by using an electric brake (dynamic brake). Japanese Patent Laid-Open No. 2023-164057 discloses a stage apparatus that is provided with a coarse moving stage and a fine moving stage and includes an electromagnetic actuator for contactlessly transmitting a thrust applied to the coarse moving stage to the fine moving stage.

Consider a case where in the stage apparatus disclosed in Japanese Patent Laid-Open No. 2023-164057, the electric brake is applied to the coarse moving stage to, for example, bring the stage apparatus to an emergency stop. In this case, since an electromagnetic actuator has no brake function, the movable iron core fixed to the fine moving stage constituting the electromagnetic actuator may collide with the fixed iron core fixed to the coarse moving stage during the operation of the electric brake. An increase in impact force at the time of collision may damage the stage apparatus.

### SUMMARY

The present disclosure provides a technique advantageous in suppressing impact at the time of braking operation.

According to some embodiments, a stage apparatus comprising: a first stage; a first actuator configured to drive the first stage; a second stage supported by the first stage; a second actuator configured to contactlessly transmit a thrust applied to the first stage by the first actuator to the second stage; a driver configured to drive the second actuator; and a controller configured to control the first actuator and the driver, wherein in a case of applying an electric brake to the first stage by using the first actuator, the controller is configured to apply the electric brake after a lapse of a predetermined time since output of control signal for controlling the second actuator from the driver is stopped, is provided.

Features of the present disclosure will become apparent from the following description of embodiments with reference to the attached drawings. The following description of embodiments is described by way of example.

### BRIEF DESCRIPTION OF THE DRAWINGS

FIG. 1 is a view showing a configuration example of a lithography apparatus as one aspect of the present disclosure;

FIG. 2 is a view showing a configuration example of a stage apparatus according to the present disclosure;

FIG. 3 is a graph exemplarily showing the velocities and accelerations of a coarse moving stage and a fine moving stage at the time of a normal operation;

FIG. 4 is a graph exemplarily showing the velocities and accelerations of the coarse moving stage and the fine moving stage at the time of emergency stop during constant velocity driving;

FIG. 5 is a graph exemplarily showing the velocities and accelerations of the coarse moving stage and the fine moving stage at the time of emergency stop during acceleration driving;

FIG. 6 is a graph exemplarily showing the velocities and accelerations of the coarse moving stage and the fine moving stage at the time of emergency stop at a substrate stage according to the present disclosure;

FIG. 7 is a graph exemplarily showing the transient characteristic of the actuator of the fine moving stage; and

FIG. 8 is a view showing a configuration example of the stage apparatus according to the present disclosure.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

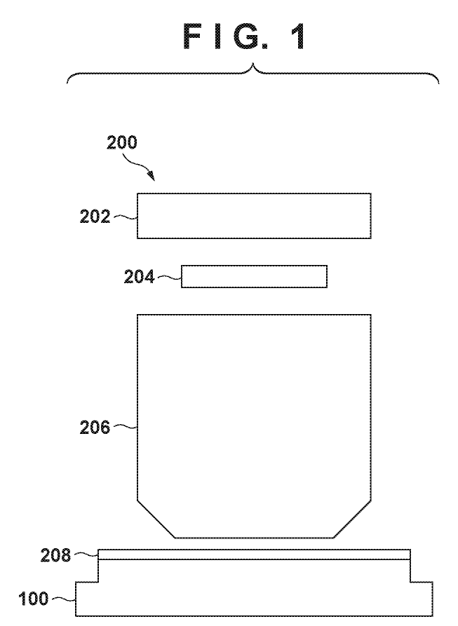

FIG. 1 is a schematic view showing a configuration example of a lithography apparatus 200 as one aspect of the present disclosure. The lithography apparatus 200 is an apparatus that forms (transfers) a pattern onto a substrate and is implemented as an exposure apparatus that forms a pattern on a substrate by exposing the substrate to light through a projection optical system. Note however that the lithography apparatus 200 is not limited to an exposure apparatus. For example, the lithography apparatus 200 may be a drawing apparatus that forms a pattern on a substrate by drawing the pattern on the substrate with a charged particle beam (an electron beam, ion beam, or the like) through a charged particle optical system. In addition, the lithography apparatus 200 may be an imprint apparatus that forms a pattern on a substrate by molding (shaping) an imprint material (such as a resin) on the substrate using a mold.

As shown in FIG. 1, the lithography apparatus 200 can include an illumination optical system 202, a reticle stage (not shown) that holds a reticle 204, a projection optical system 206, and a stage apparatus 100 that holds a substrate 208. In the lithography apparatus 200, light from a light source (not shown) illuminates the reticle 204 held on the reticle stage through the illumination optical system 202. The light passing through the reticle 204 is applied to the substrate 208 through the projection optical system 206 (that is, an image of the pattern on the reticle 204 is formed on the substrate 208). The stage apparatus 100 is a movable holding apparatus that holds the substrate 208. A specific configuration of the stage apparatus 100 in the present embodiment will be described below.

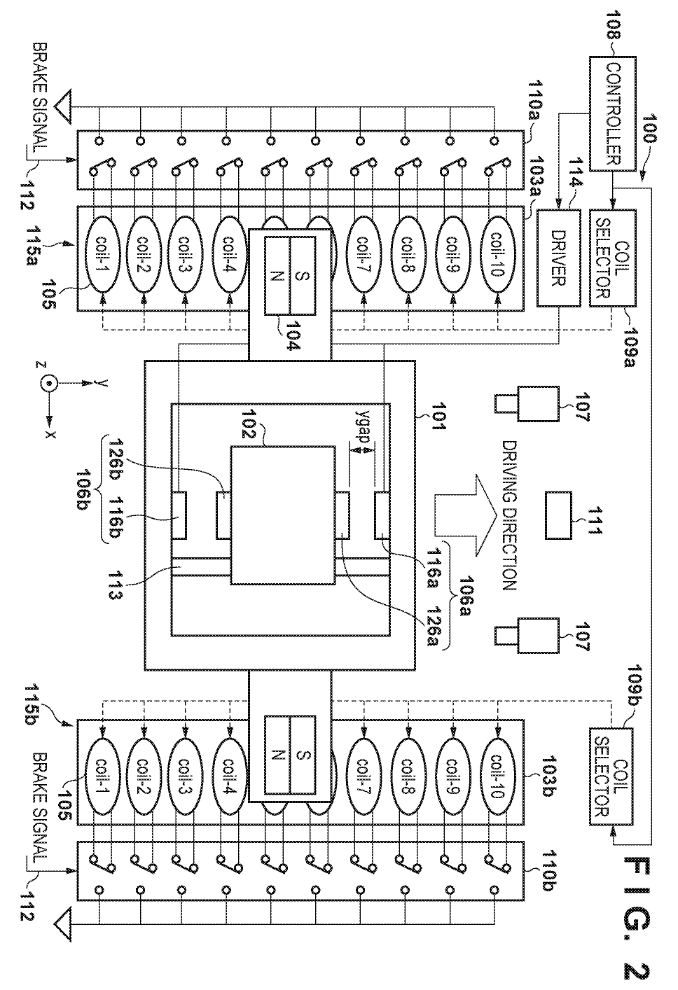

FIG. 2 is a schematic view showing a configuration example of the stage apparatus 100 according to the present embodiment and is a view of the stage apparatus 100 seen from above (the Z direction). The stage apparatus 100 is configured to include a stage with a large stroke and a large thrust (to be referred to as a coarse moving stage 101 hereinafter) and a stage with a small stroke and high positioning accuracy (to be referred to as a fine moving stage 102 hereinafter).

The coarse moving stage 101 is driven in a predetermined direction (the ± Y direction in FIG. 2) by actuators 103a and 103b. The actuators 103a and 103b can be linear motors including coil arrays 115a and 115b respectively arranged on the + side and the - side of the coarse moving stage 101 in the X direction. The coil arrays 115a and 115b respectively include a plurality of coils 105 indicated by Coil-1 to Coil-10 arranged along the Y direction (traveling direction) as the moving direction. Magnets 104 are fixed to the coarse moving stage 101. The magnets 104 respectively face the coil arrays 115a and 115b and can move above them. The magnet 104 has an N pole and an S pole and obtains a thrust by sending a current through the coil 105 facing the magnet 104 so as to generate Lorentz force. This enables the coarse moving stage 101 to move in the Y direction between the coil arrays 115a and 115b.

The fine moving stage 102 is supported by a gravity compensation/canceling mechanism and the like contactlessly with the coarse moving stage 101. The fine moving stage 102 is driven independently of the operation of the coarse moving stage 101. The fine moving stage 102 is driven by actuators 106a and 106b and an actuator 113.

The actuators 106a and 106b are respectively arranged on the + side and the - side of the fine moving stage 102 in the Y direction. The actuators 106a and 106b can be electromagnetic actuators respectively including electromagnets 116a and 116b as elements fixed on the coarse moving stage 101 and magnetic bodies 126a and 126b as elements fixed on the fine moving stage 102. The electromagnets 116a and 116b include coils that generate magnetic fields upon receiving control currents. The generated magnetic fields form a magnetic path between the magnetic bodies 126a and 126b to generate attracting force. For example, in a case where the coarse moving stage 101 is to be moved in the + Y direction, the fine moving stage 102 is controlled by the actuator 106a at the time of the acceleration of the coarse moving stage 101, whereas the fine moving stage 102 is controlled by the actuator 106b at the time of deceleration of the coarse moving stage 101. The actuators 106a and 106b contactlessly transmit a thrust applied to the coarse moving stage 101 to the fine moving stage 102 in cooperation with the actuators 103a and 103b. There is a gap ygap between an electromagnet 116 fixed to the coarse moving stage 101 and a magnetic body 126 fixed to the fine moving stage 102.

As the actuator 113, for example, a linear motor is used. The actuator 113 can minutely move the fine moving stage 102 relative to the coarse moving stage 101 in the Y direction. The actuator 113 can perform fine positioning control with a small thrust as compared with the actuators 103a and 103b and the actuators 106a and 106b. This enables the actuator 113 to perform fine adjustment for accurately positioning the fine moving stage 102.

The stage apparatus 100 has impact absorption units 107 provided at an end of the stroke range of the coarse moving stage 101. The impact absorption unit 107 has a fail safe function of mechanically receiving and stopping the coarse moving stage 101 itself, for example, at the malfunction of the coarse moving stage 101, such as when the coarse moving stage 101 fails to stop. FIG. 2 shows only the impact absorption units 107 provided on the + side in the Y direction in the stroke range of the coarse moving stage 101 but does not show the impact absorption units that can be provided on the - side.

A controller 108 can be a computer including, for example, a CPU and a memory. The controller 108 stores the driving profile of the stage apparatus 100. The controller 108 controls the movement of the coarse moving stage 101 and the fine moving stage 102 by controlling the actuators 103a and 103b, the actuators 106a and 106b, the actuator 113, and the like in accordance with this driving profile.

Coil selectors 109a and 109b select coils as current supply targets from the plurality of coils 105 arranged in the coil arrays 115a and 115b and supply currents corresponding to current control signals to the selected coils under the control of the controller 108.

A driver 114 outputs control signals for applying currents to the electromagnets 116a and 116b of the actuators 106a and 106b in accordance with current command values output from the controller 108. With this operation, the driver 114 drives the actuators 106a and 106b under the control of the controller 108. Upon receiving an output interruption command to stop the operation of the driver 114 from the controller 108, the driver 114 can stop the output of control signals for controlling the driving of the actuators 106a and 106b.

Switch units 110a and 110b include a plurality of contacts respectively connected to the coils 105. A position measurement unit 111 measures the positions of the coarse moving stage 101 and the fine moving stage 102. The controller 108 can perform feedback control of the positions of the coarse moving stage 101 and the fine moving stage 102 based on the positions of the coarse moving stage 101 and the fine moving stage 102 which are measured by the position measurement unit 111.

At the time of a normal operation of the coarse moving stage 101, the controller 108 transmits current control signals to the coil selectors 109a and 109b. The coil selectors 109a and 109b supply currents to the selected coils of the plurality of coils 105 in accordance with the received current control signals. Switching current supply will sequentially generate Lorentz force in the plurality of coils 105 to drive the coarse moving stage 101 to which the magnet 104 is fixed in, for example, the arrow direction in FIG. 2. The contacts included in the switch units 110a and 110b are all closed in the configuration shown in FIG. 2 but are open at the time of a normal operation.

The operation of an electric brake (dynamic brake) for emergency stop of the coarse moving stage 101 will be described next. At the time of emergency, the controller 108 transmits brake signals 112 to the switch units 110a and 110b and closes an electric circuit including the specific coil 105 (Coil-n (n is an arbitrary integer from 1 to 10)) (forms a closed circuit). The brake signals 112 at the time of emergency are transmitted in a case where, for example, the differences between the target positions of the coarse moving stage 101 and the fine moving stage 102 and the measured positions supplied from the position measurement unit 111 are large. If the coarse moving stage 101 is continuously driven in this state, induced electromotive force is generated in a closed circuit including the coil 105 with the closed contact. This induced electromotive force causes a current to flow in a direction to interfere with the movement of the coarse moving stage 101, thus generating braking force proportional to the velocity of the stage on the coarse moving stage 101. Making all the coils 105 form similar closed circuits will reduce the driving velocity of the coarse moving stage 101 due to braking force from the coils 105 along which the coarse moving stage 101 sequentially passes.

On the other hand, with regard to the fine moving stage 102, at the time of emergency, the controller 108 sets a current control value supplied to the driver 114 to a value for stopping the operations of the actuators 106a and 106b (stopping the application of currents to the electromagnets 116a and 116b). The controller 108 may supply, for example, a current control value for stopping the operation of the driver 114 to the driver 114 or may stop the supply of power to the driver 114. With this operation, at the time of emergency, only the supply of power to the actuators 106a and 106b for the fine moving stage 102 is stopped, and no braking force is generated in the actuators 106a and 106b. In addition, as described above, the thrust of the actuator 113 is small as compared with the actuators 103a and 103b and the actuators 106a and 106b. Accordingly, the fine moving stage 102 can also be regarded as not having a braking function. For this reason, if, for example, the coarse moving stage 101 moves in the + Y direction, the electromagnet 116a fixed to the coarse moving stage 101 and the magnetic body 126a fixed to the fine moving stage 102 gradually come close to each other and eventually collide with each other.

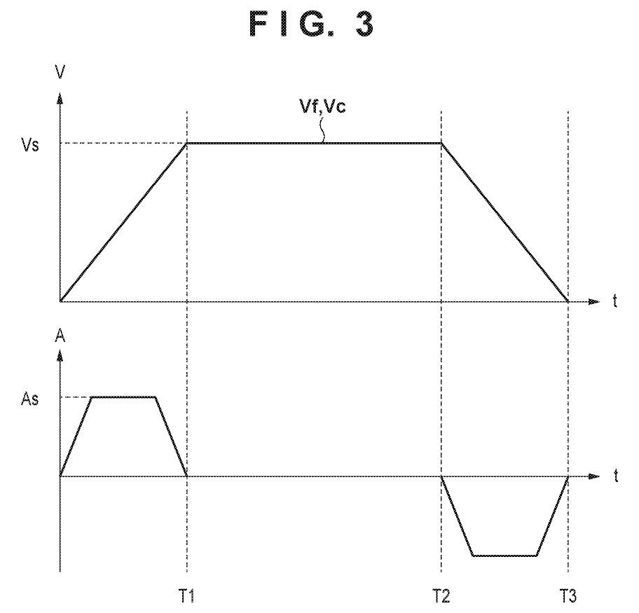

FIG. 3 is a graph showing the velocities (upper side) and accelerations (lower side) of the coarse moving stage 101 and the fine moving stage 102 with respect to a predetermined reference point on the stage apparatus 100 at the time of a normal operation. Referring to FIG. 3, Vc represents the velocity of the coarse moving stage 101, and Vf represents the velocity of the fine moving stage 102. The coarse moving stage 101 and the fine moving stage 102 accelerate from the start of driving to time T1 and reach a target velocity Vs. Thereafter, exposure processing is performed while the stages are driven at the constant velocity Vs. After the exposure processing, the stages start to decelerate from time T2 and reach a velocity of 0 at time T3. Subsequently, the stages accelerate in the inverse direction and are driven in a similar manner. While these operations are repeated, exposure processing is performed on the entire surface of a substrate such as a wafer.

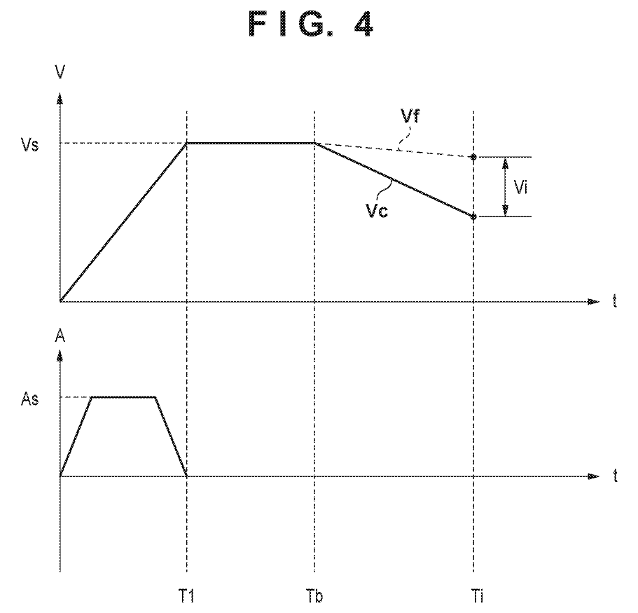

FIG. 4 is a graph showing the velocities and accelerations of the coarse moving stage 101 and the fine moving stage 102 in a case where an electric brake is activated during constant velocity driving from time T1 to time T2 in FIG. 3. Time Tb is the time when the controller 108 causes the actuators 103a and 103b to apply an electric brake to the coarse moving stage 101. In the present disclosure, to apply an electric brake can be to make the controller 108 apply an electric brake to the coarse moving stage 101 by controlling the actuators 103a and 103b. When an electric brake is activated, braking force is generated in the coarse moving stage 101 to make the coarse moving stage 101 decelerate. In contrast to this, since the fine moving stage 102 has no brake function as describe above, the output of control signals to the actuators 106a and 106b is interrupted and the fine moving stage 102 are kept in the constant velocity driving state. A description about the actuator 113 will be omitted because the obtained thrust is small as described above.

After time Tb, the coarse moving stage 101 decelerates, and the fine moving stage 102 is kept driven at a constant velocity. This gradually reduces the gap ygap between the electromagnet 116 fixed to the coarse moving stage 101 and the magnetic body 126 fixed to the fine moving stage 102. Thereafter, at time Ti, the electromagnet 116 fixed to the coarse moving stage 101 collides with the magnetic body 126 fixed to the fine moving stage 102 (this is sometimes expressed as "the coarse moving stage 101 collides with the fine moving stage 102" hereinafter). The impact force at the time of collision is determined by the difference between the velocity Vc of the coarse moving stage 101 and the velocity Vf of the fine moving stage 102, that is, a relative velocity Vi. Since the relative velocity Vi and the impact force at the time of collision have a proportional relation, the relative velocity Vi at the time of collision needs to be reduced to reduce the impact force.

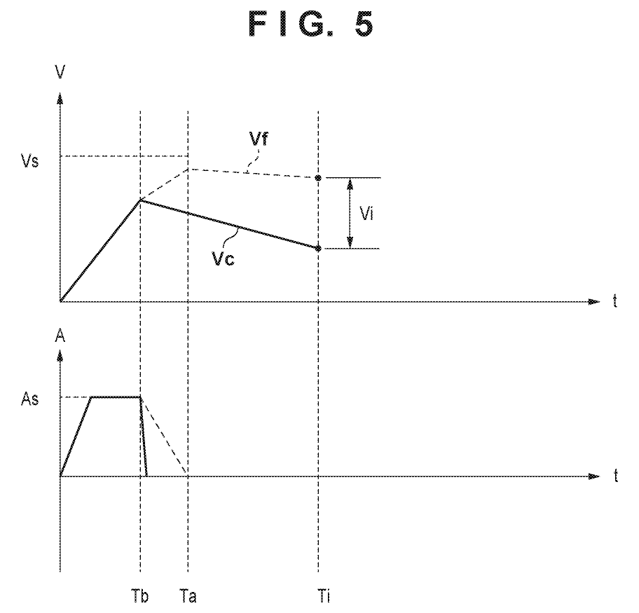

The following will describe an operation in a case where an electric brake is activated while the coarse moving stage 101 accelerates. FIG. 5 is a graph showing the velocities and accelerations of the coarse moving stage 101 and the fine moving stage 102 in a case where an electric brake is activated during acceleration driving from the start of driving of the coarse moving stage 101 to time T1 in FIG. 3. At time Tb, braking force is generated by the activation of an electric brake in the coarse moving stage 101, and the coarse moving stage 101 decelerates in the same manner as at the time of the activation of an electric brake during constant velocity driving. On the other hand, although the output of control signals to the actuators 106a and 106b is interrupted, the fine moving stage 102 keeps accelerating for a predetermined time because currents are caused to flow by the induced electromotive force generated in the coils of the electromagnets 116a and 116b. If, for example, the fine moving stage 102 is accelerating in the + Y direction in FIG. 2, the force in the pulling direction of the magnetic body 126a remains until the current flowing in the electromagnet 116a of the actuator 106a becomes 0. This makes the velocity Vf of the fine moving stage 102 become higher than that at time Tb when the electric brake is activated. Accordingly, it is assumed that the fine moving stage 102, which keeps accelerating for a predetermined time from time Tb when the electric brake is activated, collides at time Ti with the coarse moving stage 101, which starts to decelerate and gradually loses speed. In this case, the relative velocity Vi increases as compared with a case where an electric brake is activated at the time of constant velocity driving. Therefore, the impact force at the time of collision between the coarse moving stage 101 and the fine moving stage 102 becomes larger than that in a case where an electric brake is activated at the time of constant velocity driving.

In the present embodiment, in a case where an electric brake is applied to the coarse moving stage 101 at the time of, for example, emergency, first of all, the controller 108 stops the output of control signals for controlling the actuators 106a and 106b from the driver 114 and stops the supply of power to the actuators 106a and 106b that drive the fine moving stage 102. After the lapse of a predetermined time Td (to be sometimes simply referred to as the time Td), the controller 108 controls the actuators 103a and 103b to apply an electric brake to the coarse moving stage 101.

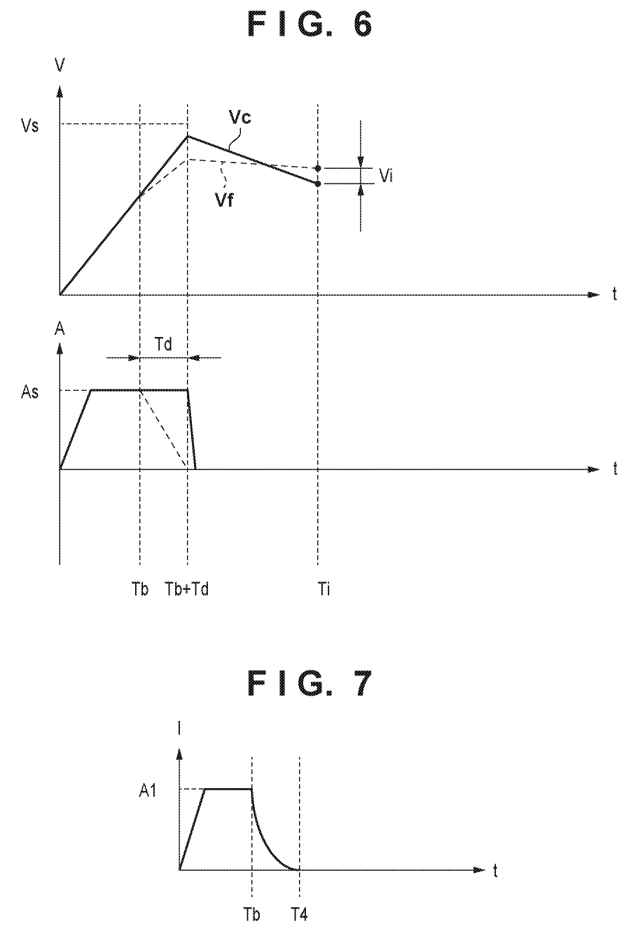

FIG. 6 shows the velocities and accelerations of the coarse moving stage 101 and the fine moving stage 102 at the time of emergency in the present embodiment. If an abnormality is detected at time Tb, the controller 108 stops, first of all, the supply of currents to the actuators 106a and 106b that drive the fine moving stage 102. The controller 108 stops the supply of power to the actuators 106a and 106b by stopping the output of control signals from the driver 114 to the actuators 106a and 106b. In addition, at time Tb, the controller 108 may also stop the supply of a current to the actuator 113 to stop its driving. At this time, the controller 108 keeps control to cause the coarse moving stage 101 to continuously accelerate during the time Td without applying any electric brake to the coarse moving stage 101.

After the lapse of the predetermined time Td, the controller 108 controls the actuators 103a and 103b to apply an electric brake to the coarse moving stage 101 to make the coarse moving stage 101 decelerate. Thereafter, the gap ygap between the magnetic body 126 fixed to the fine moving stage 102 and the electromagnet 116 fixed to the coarse moving stage 101 decreases to eventually make them collide with each other. However, the relative velocity Vi at the time of collision becomes smaller than that when an electric brake is immediately applied to the coarse moving stage 101 at the time of emergency. That is, using the driving method according to the present embodiment makes it possible to reduce the impact force at the time of collision even when, for example, a brake for emergency stop is activated during acceleration driving.

The relative velocity Vi at the time of collision can be calculated from, for example, the operation states of the actuators 103a and 103b and the actuators 106a and 106b at the time of the activation of an electric brake after the lapse of the time Td from the timing (time Tb) when the press of an emergency button or an abnormality is detected. More specifically, the relative velocity Vi can be calculated from the velocity of the coarse moving stage 101, the velocity of the fine moving stage 102, and the braking force applied to the coarse moving stage 101 after the lapse of the time Td from time Tb. The velocity of the coarse moving stage 101 after the lapse of the time Td is determined by the accelerations obtained by using the actuators 103a and 103b of the coarse moving stage 101 and the time Td. The velocity of the fine moving stage 102 after the lapse of the time Td can be obtained from the accelerations generated in accordance with the characteristics of the actuators 103a and 103b and the fine moving stage 102 when the supply of control signals is stopped in the actuators 106a and 106b.

Consider the acceleration of the fine moving stage 102 in a case where the supply of control signals to the actuators 106a and 106b which drive the fine moving stage 102 is stopped. FIG. 7 shows the currents flowing through the electromagnets 116a and 116b of the actuators 106a and 106b in a case where the output of control signals from the driver 114 to the actuators 106a and 106b which drive the fine moving stage 102 is shut down (stopped). When the supply of control signals during the application of a current value A1 is stopped, the current values of currents flowing through the electromagnets 116a and 116b gradually decrease and become 0 at time T4. The currents flowing from time Tb to time T4 cause the actuators 106a and 106b to make the fine moving stage 102 generate acceleration. This makes it possible to calculate the acceleration of the fine moving stage 102 from the thrust generated in the fine moving stage 102 in accordance with the transient characteristics of the actuators 106a and 106b. This makes it possible to obtain the velocity of the fine moving stage 102 after the lapse of the predetermined time Td and calculate the relative velocity Vi at the time of collision. The relative velocity Vi at the time of collision changes depending on the timing and time Td during acceleration driving. Accordingly, it is possible to reduce the impact force at the time of collision between the coarse moving stage 101 and the fine moving stage 102 by determining the time Td so as to reduce the relative velocity between the coarse moving stage 101 and the fine moving stage 102 to an allowable relative velocity or less.

Accordingly, the time Td may be set in accordance with the characteristics of the actuators 106a and 106b and the fine moving stage 102 in a case where the supply of control signals to the actuators 106a and 106b is stopped. As described above, for example, the characteristics of the actuators 106a and 106b can be the transient characteristics of the actuators 106a and 106b in a case where the supply of control signals to the actuators 106a and 106b is stopped. The characteristic of the fine moving stage 102 can be the thrust generated in the fine moving stage 102 by an attracting force originating from the weight of the fine moving stage 102 and the transient characteristics of the actuators 106a and 106b. The transient characteristics of the actuators 106a and 106b which drive the fine moving stage 102 and the thrust generated in the fine moving stage 102 in accordance with the transient characteristics can be calculated from the design values of the stage apparatus 100 including the fine moving stage 102 and the actuators 106a and 106b.

Consider a case where, for example, the fine moving stage 102 and the actuators 106a and 106b include individual differences. The actuators 106a and 106b and the fine moving stage 102 are made to execute predetermined operations in advance under a plurality of conditions in accordance with various types of driving profiles for driving the stage apparatus 100. With this operation, the transient characteristics of the actuators 106a and 106b and the thrust generated in the fine moving stage 102 in accordance with the transient characteristics may be measured, and the time Td may be set in accordance with various types of driving profiles based on the measured values.

The time Td may be stored, in accordance with each type of driving profile in, for example, a memory provided in the controller 108 which stores the driving profiles of the stage apparatus 100. The controller 108 may determine the time Td to be used in practice from a plurality of delay times set in accordance with the operation states of the actuators 103a and 103b and the actuators 106a and 106b based on various types of driving profiles at the time of the application of an electric brake. Each driving profile is set in accordance with, for example, the acceleration of the coarse moving stage 101, the time of acceleration, the distance by which the coarse moving stage 101 is moved, and the like.

The effect of the time Td may be small when an electric brake is activated during constant velocity driving or deceleration driving as compared with during acceleration driving. This is because, for example, the attracting force of the actuators 106a and 106b can be reduced (for example, to 0), the currents flowing through the electromagnets 116a and 116b can be reduced, and the influence of the transient characteristics can be reduced during constant velocity driving as compared with during acceleration driving. In addition, during deceleration driving, attracting force is generated in the actuators 106a and 106b arranged in a direction opposite to the direction in which the braking force generated by an electric brake is applied. This is because the attracting force (thrust) generated by the transient characteristic may cause the fine moving stage 102 to decelerate relative to the coarse moving stage 101. Accordingly, the controller 108 may determine the time Td in accordance with acceleration driving, constant velocity driving, deceleration driving, or the like in each type of driving profile as the operation states of the actuators 103a and 103b and the actuators 106a and 106b. For example, as described above, in a case where an electric brake is applied to the coarse moving stage 101 during acceleration driving, the controller 108 sets a predetermined time as the time Td. In contrast to this, in a case where an electric brake is applied to the coarse moving stage 101 during constant velocity driving or deceleration driving, the controller 108 may set the time Td to, for example, 0 sec. That is, the controller 108 may perform control to apply an electric brake to the coarse moving stage 101 simultaneously with stopping the output of control signals from the driver 114 to the actuators 106a and 106b.

Consider a case where the supply of power to the stage apparatus 100 is interrupted at the time of emergency, for example, a power failure. Even in such a case, the above operation can be implemented by providing the stage apparatus 100 with, for example, a battery that operates for a predetermined time. In addition, for example, the above operation can be implemented by providing the controller 108, the switch units 110a and 110b, or the like with a battery (for example, a capacitor) or counter that operates for a predetermined time.

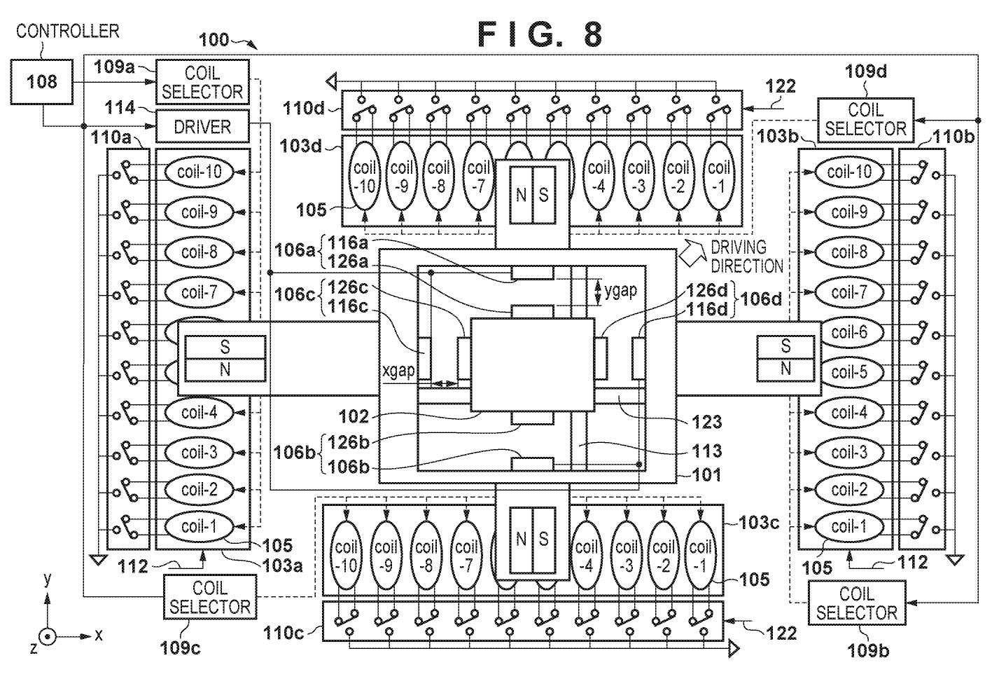

FIG. 8 is a schematic view showing a configuration example of the stage apparatus 100 according to the present embodiment and a modification of the configuration example shown in FIG. 2. The stage apparatus 100 shown in FIG. 8 is additionally provided with an actuator so as to be driven in the ± X direction intersecting the ± Y direction as well as in the ± Y direction. The stage apparatus 100 is configured to include the coarse moving stage 101 with a large stroke and a large thrust and the fine moving stage 102 with a small stroke and high positioning accuracy.

The coarse moving stage 101 is driven in the ± Y direction by the actuators 103a and 103b as in the configuration shown in FIG. 2. In addition, the coarse moving stage 101 is driven in the ± X direction by actuators 103c and 103d. The actuators 103cand 103d can be linear motors configured to include the plurality of coils 105 like the actuators 103a and 103b.

The fine moving stage 102 is supported by a gravity compensation/canceling mechanism and the like contactlessly with the coarse moving stage 101. The fine moving stage 102 is driven in the Y direction and the X direction independently of the operation of the coarse moving stage 101. The fine moving stage 102 is driven with higher resolution than the coarse moving stage 101 and allows fine adjustment in positioning of a target. The fine moving stage 102 is driven in the Y direction by the actuators 106a and 106b and the actuator 113 as in the configuration shown in FIG. 2. In addition, the fine moving stage 102 is driven in the X direction by the actuators 106c and 106d and an actuator 123.

The actuators 106c and 106d are respectively arranged on the + side and the - side of the fine moving stage 102 in the X direction. Like the actuators 106a and 106b described above, the actuators 106c and 106d can be electromagnetic actuators respectively including electromagnets 116c and 116d fixed on the coarse moving stage 101 and magnetic bodies 126c and 126d fixed on the fine moving stage 102. The actuators 106a, 106b, 106c, and 106d contactlessly transmit a thrust applied to the coarse moving stage 101 to the fine moving stage 102 in cooperation with the actuators 103a, 103b, 103c, and 103d. There are gaps ygap in the Y direction between the electromagnets 116a and 116b fixed to the coarse moving stage 101 and magnetic bodies 126a and 126b fixed to the fine moving stage 102. There are gaps xgap in the X direction between the electromagnets 116c and 116d fixed to the coarse moving stage 101 and magnetic bodies 126c and 126d fixed to the fine moving stage 102.

The actuator 113 is an actuator for minutely moving the fine moving stage 102 relative to the coarse moving stage 101 in the Y direction. The actuator 123 is an actuator for minutely moving the fine moving stage 102 relative to the coarse moving stage 101 in the X direction. As the actuator 123, like the actuator 113, a linear motor may be used. The actuators 113 and 123 can perform fine positioning control with a small thrust as compared with the actuators 103a to 103d and the actuators 106a to 106d. This enables the actuators 113 and 123 to perform fine adjustment for accurately positioning the fine moving stage 102.

The controller 108 is a computer including, for example, a CPU and a memory and stores a driving profile for the stage apparatus 100. The controller 108 controls the movement of the coarse moving stage 101 and the fine moving stage 102 by controlling the actuators 103a to 103d, the actuators 106a to 106d, the actuators 113 and 123, and the like in accordance with this driving profile.

The coarse moving stage 101 can be driven by causing the controller 108 to control the coil selectors 109ato 109dand supplying currents to arbitrary coils of the actuators 103ato 103d. The switch units 110ato 110dinclude a plurality of contacts respectively connected to the coils 105 of the actuators 103a to 103d. The contacts included in the switch units 110ato 110dare all closed in the configuration shown in FIG. 8 but are all open at the time of a normal operation.

The driver 114 outputs control signals for applying currents to the electromagnets 116a to 116d of the actuators 106ato 106d in accordance with current command values output from the controller 108. With this operation, the driver 114 drives the actuators 106a to 106d under the control of the controller 108. In addition, upon receiving an output interruption command to stop the operation of the driver 114 from the controller 108, the driver 114 can stop the output of control signals for controlling the driving of the actuators 106a to 106d.

In the stage apparatus 100 shown in FIG. 8, in a case where an electric brake is activated at the time of emergency or the like, the controller 108 transmits the brake signals 112 to the switch units 110a and 110b respectively connected to the actuators 103a and 103b. The controller 108 transmits brake signals 122 to the switch units 110c and 110d respectively connected to the actuators 103c and 103d. This causes the switch units 110ato 110dto close an electric circuit including the specific coil 105 to form a closed circuit. The controller 108 can independently control the timing of applying electric brakes to the actuators 103a and 103b and the timing of applying electric brakes to the actuators 103c and 103d in accordance with the brake signals 112 and 122.

In the stage apparatus 100, the coarse moving stage 101 and the fine moving stage 102 are driven at arbitrary velocities in the X and Y directions. Accordingly, it is necessary to obtain the relative velocity Vi at the time of collision so as to make the impact force at the time of collision between the coarse moving stage 101 and the fine moving stage 102 become equal to or lower than allowable stress in each direction when an electric brake is activated at the time of emergency or the like. A relative velocity Viy in the Y direction can be calculated from the velocity of the coarse moving stage 101 in the Y direction, the velocity of the fine moving stage 102 in the Y direction, and the braking force acting on the coarse moving stage 101 in the Y direction after the lapse of a predetermined time Tdy since time Tb when an abnormality is detected as described above. Likewise, a relative velocity Vix in the X direction can be calculated from the velocity of the coarse moving stage 101 in the X direction, the velocity of the fine moving stage 102 in the X direction, and the braking force acting on the coarse moving stage 101 in the X direction after the lapse of a predetermined time Tdx since time Tb. The velocities of the fine moving stage 102 in the Y and X directions can be obtained from the characteristics of the thrust generated in the fine moving stage 102 in accordance with the transient characteristics of the actuators 106a to 106d as in the above manner in a case where the supply of control signals to the actuators 106ato 106dis stopped. The impact force at the time of collision between the coarse moving stage 101 and the fine moving stage 102 can be reduced by determining times Tdy and Tdx so as to make the relative velocities in the Y and X directions become equal to or less than the relative velocities Viy and Vix.

On the other hand, in a case where the coarse moving stage 101 collides with the fine moving stage 102, the timing of collision in the Y direction sometimes coincides with the timing of collision in the X direction depending on the manner of selecting the times Tdy and Tdx. In such a case, the impact force at the time of collision corresponds to the synthesized velocity of the relative velocities in the respective directions instead of the relative velocity in each direction. If the impact force corresponding to the synthesized velocity exceeds the allowable stress between the coarse moving stage 101 and the fine moving stage 102, the coarse moving stage 101 or the fine moving stage 102 may be damaged. Accordingly, when determining the times Tdy and Tdx, the controller 108 determines the times Tdy and Tdx so as to shift the timing of collision in the Y direction from the timing of collision in the X direction within ranges equal to or less than the relative velocities Viy and Vix. This makes it possible to prevent the timings of collision in the Y direction and collision in the X direction from coinciding with each other. This eventually reduces the possibility of damage on the coarse moving stage 101 and the fine moving stage 102.

An article manufacturing method according to an embodiment of the present disclosure is suitable for manufacturing an article, for example, a microdevice such as a semiconductor device or an element having a fine structure. The article manufacturing method according to the present embodiment includes a step of transferring (for example, exposing) the pattern of an original plate onto a substrate by using the lithography apparatus 200 (an exposure apparatus, imprint apparatus, drawing apparatus, or the like) and a step of processing (for example, developing) the substrate on which the pattern is transferred in the transfer step. In addition, this manufacturing method can include other known steps (oxidation, deposition, vapor deposition, doping, planarization, etching, resist removal, dicing, bonding, packaging, and the like). The article manufacturing method according to the present embodiment is advantageous in at least one of the performance, quality, productivity, and production cost of the article, as compared to conventional methods.

While the present disclosure has been described with reference to the embodiments of the present disclosure, it is to be understood that the present disclosure is not limited to these embodiments and can be variously modified and changed within the scope of the gist. For example, the present disclosure is not limited to the lithography apparatus 200 and can be applied to other apparatuses (a measurement apparatus and the like) including the stage apparatus 100.

According to the present disclosure, it is possible to provide a technique advantageous in suppressing the impact at the time of a braking operation.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-014097, filed January 30, 2025, which is hereby incorporated by reference herein in its entirety.

What is claimed is:

1. A stage apparatus comprising:
a first stage;
a first actuator configured to drive the first stage;
a second stage supported by the first stage;
a second actuator configured to contactlessly transmit a thrust applied to the first stage by the first actuator to the second stage;
a driver configured to drive the second actuator; and
a controller configured to control the first actuator and the driver,
wherein in a case of applying an electric brake to the first stage by using the first actuator, the controller is configured to apply the electric brake after a lapse of a predetermined time since output of control signal for controlling the second actuator from the driver is stopped.

2. The apparatus according to claim 1, wherein the controller is configured to determine the predetermined time in accordance with operation states of the first actuator and the second actuator in a case of applying the electric brake.

3. The apparatus according to claim 1, wherein the predetermined time is set in accordance with characteristics of the second actuator and the second stage in a case where supply of the control signal to the second actuator is stopped.

4. The apparatus according to claim 3, wherein the characteristic includes a characteristic of the thrust generated in the second stage in accordance with a transient characteristic of the second actuator in a case where supply of the control signal to the second actuator is stopped.

5. The apparatus according to claim 3, wherein the predetermined time is set based on design values of the second actuator and the second stage, or is set based on a measured value measured by causing the second actuator and the second stage to execute predetermined operations.

6. The apparatus according to claim 1, wherein the controller is configured to apply the electric brake after lapse of the predetermined time since output of the control signal from the driver is stopped in a case of causing the first actuator to apply the electric brake to the first stage while causing the first actuator to make the first stage accelerate.

7. The apparatus according to claim 1, wherein the first actuator includes a linear motor.

8. The apparatus according to claim 1, wherein the second actuator includes an electromagnetic actuator.

9. The apparatus according to claim 1, wherein the controller stops output of the control signal by the driver by stopping an operation of the driver.

10. The apparatus according to claim 1, wherein the first actuator moves the first stage in a first direction,
the stage apparatus further includes a third actuator configured to drive the first stage to move the first stage in a second direction intersecting the first direction,
the second actuator contactlessly transmits a thrust applied to the first stage by the first actuator and the third actuator to the second stage, and
in a case of applying the electric brake to the first stage by using the first actuator and the third actuator while setting the predetermined time as a first predetermined time, the controller is configured to cause the first actuator to apply the electric brake after lapse of the first predetermined time since output of the control signal from the driver is stopped and is configured to cause the third actuator to apply the electric brake after lapse of a second predetermined time since output of the control signal from the driver is stopped.

11. The apparatus according to claim 10, wherein the second actuator includes a first element fixed to the first stage and a second element fixed to the second stage which are configured to transmit a thrust applied to the first stage by the first actuator and a third element fixed to the first stage and a fourth element fixed to the second stage which are configured to transmit a thrust applied to the first stage by the third actuator, and
in a case of causing the first actuator and the third actuator to apply the electric brake to the first stage, the controller is configured to determine the first predetermined time and the second predetermined time so as to shift a timing of collision between the first element and the second element from a timing of collision between the third element and the fourth element.

12. A lithography apparatus that transfers a pattern of an original onto a substrate, the apparatus comprising the stage apparatus according to claim 1.

13. An article manufacturing method comprising:
forming a pattern on a substrate by using the lithography apparatus according to claim 12; and
processing the substrate on which the pattern is formed.

14. A method of driving a stage apparatus, the stage apparatus including a first stage, a first actuator configured to drive the first stage, a second stage supported by the first stage, a second actuator configured to contactlessly transmit a thrust applied to the first stage by the first actuator to the second stage, and a driver configured to drive the second actuator,
the method comprising in a case of causing the first actuator to apply an electric brake to the first stage, applying the electric brake after a lapse of a predetermined time since output of a control signal for controlling the second actuator from the driver is stopped.
